(19) United States
(12) Patent Application Publication
(10) Pub. No.: US 2026/0033160 A1
(43) Pub. Date: Jan. 29, 2026

(54) DISPLAY PANEL AND METHOD OF MANUFACTURING DISPLAY PANEL

(71) Applicant: HKC CORPORATION LIMITED, SHENZHEN (CN)

(72) Inventors: Dongmei WEI, SHENZHEN (CN); Zhonglin CAO, SHENZHEN (CN); Chuan WU, SHENZHEN (CN); Lidan YE, SHENZHEN (CN)

(73) Assignee: HKC CORPORATION LIMITED, SHENZHEN (CN)

(21) Appl. No.: 19/260,451

(22) Filed: Jul. 5, 2025

(30) Foreign Application Priority Data
Jul. 23, 2024 (CN) 202410994925.6

(51) Int. Cl. H10K 59/123; H10K 59/12

(52) U.S. Cl. CPC H10K 59/123; H10K 59/1201

(57) ABSTRACT

A display panel is provided. A glass substrate has a first surface and a second surface and has conductive through holes extending from the first surface to the second surface. The conductive through holes include first conductive through holes. Light emitting units are arranged on the first surface. Each light emitting unit includes an anode electrode, an organic light emitting layer and a cathode electrode that are stacked sequentially. Bonding portions are arranged on the second surface. Each bonding portion is electrically connected to the anode electrode through the first conductive through hole. A silicon-based driver substrate is arranged on a side of the second surface and includes bonding electrodes. One bonding electrode is aligned to and bonded with one bonding portion. Each bonding portion has a first snap portion, and each bonding electrode has a second snap portion embeddingly connected to the first snap portion.

### CROSS REFERENCE TO RELATED APPLICATIONS

The present application claims the priority of the Chinese patent application No. 202410994925.6, filed on Jul. 23, 2024, contents of which are incorporated herein by its entireties.

### TECHNICAL FIELD

Embodiments of the present disclosure relate to the technical field of displaying, and more specifically, to a display panel and a method of manufacturing a display panel.

### BACKGROUND

A monocrystalline silicon driver backplane is a driver substrate which takes a semiconductor device formed based on a complementary metal oxide semiconductor (CMOS) process as a driver unit. Compared to an active-matrix organic light-emitting diode (AMOLED) panel which takes an amorphous silicon, a microcrystalline silicon, or a low-temperature polycrystalline silicon thin-film transistor as the backplane, the monocrystalline silicon driver backplane may have a higher carrier mobility. Therefore, a silicon-based organic light-emitting diode (OLED) display panel may be a best performance display panel to be used in AR/VR products.

Currently, for the silicon-based OLED display panel, an externally-bound display chip may be integrated into the silicon-based driver backplane. A preparation method thereof is to perform evaporation to form the OLED device on the silicon-based driver substrate. Specific processes include: firstly performing deposition to form an anode, then preparing a pixel defining layer, and then performing deposition to successively form an organic light emitting layer and a cathode. In this way, smaller-sized pixel units may be prepared, and displaying finesse even better than retina may be achieved, such that a high resolution, high integration, lower power consumption, a small size, and a light weight, can be achieved.

However, direct evaporation to form the OLED device on silicon-based driver substrate may affect a silicon-based driver circuit, resulting in damage to the driver circuit, such that the driver circuit may be unusable, increasing manufacturing costs.

### SUMMARY

The present disclosure provides a display panel and a method of manufacturing the display panel, so as to solve the technical problem of circuit damages caused by direct evaporation to form the OLED device on silicon-based driver substrate.

In a first aspect, the present disclosure provides a display panel, including:
a glass substrate, including a first surface and a second surface opposite to the first surface, wherein the glass substrate have a plurality of conductive through holes extending from the first surface to the second surface; the plurality of the conductive through holes comprises a plurality of first conductive through holes;
a plurality of light emitting units, arranged on the first surface of the glass substrate; wherein each of the plurality of light emitting units comprises an anode electrode, an organic light emitting layer and a cathode electrode that are stacked sequentially in a direction extending away from the glass substrate;
a plurality of bonding portions, arranged on the second surface of the glass substrate; wherein each of the plurality of bonding portions is electrically connected to the anode electrode of a respective one of the plurality of light emitting units through a respective one of the plurality of first conductive through holes;
a silicon-based driver substrate, arranged on a side of the second surface of the glass substrate and comprising a plurality of bonding electrodes; wherein the plurality of bonding electrodes is one-to-one aligned to and bonded with the plurality of bonding portions.

Each of the plurality of bonding portions has a first snap portion, and each of the plurality of bonding electrodes has a second snap portion; one of the first snap portion and the second snap portion is a recessed structure, and the other one of the first snap portion and the second snap portion is a protruding structure, the protruding structure is embedded in the recessed structure.

In a second aspect, the present disclosure provides a method of manufacturing a display panel, including:
providing a glass substrate, wherein the glass substrate comprises a first surface and a second surface opposite to the first surface; the glass substrate has a plurality of conductive through holes extending from the first surface to the second surface;
preparing a plurality of anode electrodes on the first surface of the glass substrate and preparing a plurality of bonding portions on the second surface of the glass substrate; wherein each of the plurality of bonding portions is electrically connected to a respective one of the plurality of anode electrodes through a respective one of the plurality of conductive through holes; each of the plurality of bonding portions has a first snap portion;
preparing a pixel defining layer and a plurality of organic light emitting layers sequentially on a side of the plurality of the anode electrodes away from the glass substrate;
providing a silicon-based driver substrate; wherein the silicon-based driver substrate comprises a plurality of bonding electrodes, each of the plurality of bonding electrodes has a second snap portion; one of the first snap portion and the second snap portion is a recessed structure, and the other one of the first snap portion and the second snap portion a protruding structure;
aligning and bonding the silicon-based driver substrate with the glass substrate arranged with the plurality of organic light emitting layers, wherein the plurality of bonding electrodes are in one-to-one aligned and bonded with the plurality of bonding portions; and the protruding structure is embedded in the recessed structure.

### BRIEF DESCRIPTION OF THE DRAWINGS

FIG. 1a is a structural schematic view of a display panel according to a first embodiment of the present disclosure.

FIG. 1b is a structural schematic view of the display panel according to another embodiment of the present disclosure.

FIG. 1c is a structural schematic view of the display panel according to still another embodiment of the present disclosure.

FIG. 2a is an enlarged view of a portion A in the display panel shown in FIG. 1.

FIG. 2b is an exploded view of the portion A shown in FIG. 2a.

FIG. 3a is an enlarged view of a portion A in the display panel according to a second embodiment of the present disclosure.

FIG. 3b is an exploded view of the portion A shown in FIG. 3a.

FIG. 4a is an enlarged view of a portion A in the display panel according to a third embodiment of the present disclosure.

FIG. 4b is an exploded view of the portion A shown in FIG. 4a.

FIG. 5a is an enlarged view of a portion A in the display panel according to a fourth embodiment of the present disclosure.

FIG. 5b is an exploded view of the portion A shown in FIG. 5a.

FIG. 6a is an enlarged view of a portion A in the display panel according to a fifth embodiment of the present disclosure.

FIG. 6b is an exploded view of the portion A shown in FIG. 6a.

FIG. 7 is a flow chart of a method of manufacturing a display panel according to an embodiment of the present disclosure.

FIG. 8 is a structural schematic view of a structure obtained after performing the operation S1.

FIG. 9a is a structural schematic view of a structure obtained after performing the operation S2.

FIG. 9b is an enlarged view of a portion C in the structure shown in FIG. 9a.

FIG. 9c is a flow chart of performing the operation S2.

FIG. 10 is a structural schematic view of a structure obtained after performing the operation S21.

FIG. 11a is a structural schematic view of a structure obtained after performing the operation S22.

FIG. 11b is an enlarged view of a portion D in the structure shown in FIG. 11a.

FIG. 12 is a structural schematic view of a structure obtained after performing the operations S23 and S24.

FIG. 13 is a structural schematic view of a structure obtained after performing the operation S25.

FIG. 14 is a structural schematic view of a structure obtained after performing the operation S3.

FIG. 15a is a structural schematic view of a structure obtained after performing the operation S4.

FIG. 15b is an enlarged view of a portion E in the structure shown in FIG. 15a.

FIG. 16 is a structural schematic view of a structure obtained after performing the operation S5.

FIG. 17 is a structural schematic view of a cathode electrode, which is electrically connected to a connection electrode and is arranged on the structure shown in FIG. 16.

### REFERENCE NUMERALS IN THE DRAWINGS

1—glass substrate; 2—light emitting unit; 3—pixel defining layer; 4—bonding portion; 5—silicon-based driver substrate; 6—photoresist layer; 11—first surface; 12—second surface; 13—conductive through holes; 21—anode electrode; 22—organic light emitting layer; 23—cathode electrode; 24—encapsulation layer; 41—first snap portion; 51—bonding electrode; 52—connection electrode; 53—monocrystalline silicon substrate; 54—driver circuit; 55—protective layer; 56—insulating layer; 61—receiving groove; 131—first conductive through hole; 132—second conductive through hole; 411—recessed structure; 511—second snap portion; 5111—protruding portion; 411a—sub-recessed structure; 5111a—sub-protruding portion.

### DETAILED DESCRIPTIONS

The technical solutions in the embodiments of the present disclosure will be clearly and completely described below by referring to the accompanying drawings in the embodiments of the present disclosure. Apparently, the described embodiments are only a part of, not all of, the embodiments of the present disclosure. All other embodiments, which are obtained by any ordinary skilled person in the art based on the embodiments in the present disclosure without making creative work, shall fall within the scope of the present disclosure.

Terms “first”, “second”, and “third” in the present disclosure are used for descriptive purposes only and are not to indicate or imply relative importance or implicitly specifying the number of technical features. Therefore, a feature defined with “first”, “second”, “third” may include at least one such feature, either explicitly or implicitly. In the description of the present disclosure, “a plurality of” means at least two, such as two, three, and so on, unless otherwise expressly and specifically limited. All directional indications (such as up, down, left, right, front, rear . . . ) in the embodiments of the present disclosure are only used to explain a relative positional relationship and movement between components at a particular attitude (the attitude as shown in the accompanying drawings). The directional indication may be changed accordingly when the particular attitude is changed. Furthermore, terms “include” and “have” and any variations thereof are intended to cover non-exclusive inclusion. For example, a process, a method, a system, a product or an apparatus including a series of steps or units is not limited to the listed steps or units, but may further include steps or units that are not listed or steps or units that are inherently included in the process, the method, the system, the product or the apparatus.

Reference to “embodiments” herein means that particular features, structures, or characteristics described in an embodiment may be included in at least one embodiment of the present disclosure. The phrase at various sections in the specification does not necessarily refer to one same embodiment, nor separate or alternative embodiments that are mutually exclusive of other embodiments. Any ordinary skilled person in the art shall understand that, both explicitly and implicitly, the embodiments described herein may be combined with other embodiments.

The present disclosure will be described in detail by referring to drawings and embodiments.

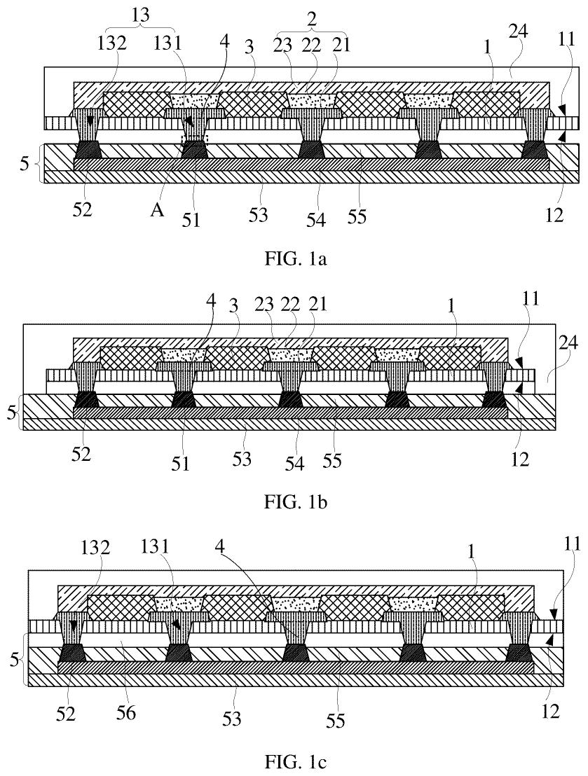

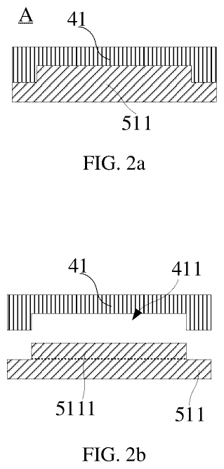

As shown in FIGS. 1a-FIG. 2b, FIG. 1a is a structural schematic view of a display panel according to a first embodiment of the present disclosure; FIG. 1b is a structural schematic view of the display panel according to another embodiment of the present disclosure; FIG. 1c is a structural schematic view of the display panel according to still another embodiment of the present disclosure; FIG. 2a is an enlarged view of a portion A in the display panel shown in FIG. 1; and FIG. 2b is an exploded view of the portion A shown in FIG. 2a. The present disclosure provides a display panel, which may be an OLED display panel. The display panel may include a glass substrate 1, a plurality of light emitting units 2, a plurality of bonding portions 4, and a silicon-based driver substrate 5.

The glass substrate 1 may include a first surface 11 and a second surface 12 opposite to the first surface 11. The glass substrate 1 defines a plurality of conductive through holes 13 extending from the first surface 11 to the second surface 12. A diameter of each of the plurality of conductive through holes 13 may be in a range of 50 μm to 100 μm. It is understood that an excessively small spacing between adjacent conductive through holes 13 of the plurality of conductive through holes 13 may affect structural strength of the glass substrate 1, causing a damage to the glass substrate 1; and an excessively large spacing between the adjacent conductive through holes 13 may affect a density of the plurality of conductive through holes 13. Therefore, the spacing of the adjacent conductive through holes 13 may be in a range of between 50 μm and 150 μm. The plurality of conductive through holes 13 may include a plurality of first conductive through holes 131.

The plurality of light emitting units 2 may be disposed on the first surface 11 of the glass substrate 1. Each of the plurality of light emitting units 2 may include an anode electrode 21, an organic light emitting layer 22, and a cathode electrode 23 that are stacked sequentially in a direction extending away from the glass substrate 1. Specifically, the first surface 11 of the glass substrate 1 is further arranged with a pixel defining layer 3. The pixel defining layer 3 protrudes out of the glass substrate 1, and the pixel defining layer 3 and the glass substrate 1 enclose to form a plurality of pixel receiving regions (not shown in the figure). The plurality of light emitting units 2 are arranged within the plurality of pixel receiving regions. The plurality of pixel receiving regions are arranged in one-to-one correspondence with the plurality of first conductive through holes 131.

The anode electrode 21 may be arranged on a surface of the glass substrate 1 exposed through the pixel receiving regions. The pixel defining layer 3 may cover an edge of the anode electrode 21 so as to prevent the anode electrode 21 of one of the plurality of light emitting units 2 from contacting the anode electrode 21 of an adjacent one of the plurality of light emitting units 2, such that signal crosstalk may be prevented. The organic light emitting layer 22 may be disposed on a side of the anode electrode 21 away from the glass substrate 1. The cathode electrode 23 may be disposed on a side of the organic light emitting layer 22 away from the anode electrode 21 and cover the organic light emitting layer 22. Specifically, one integral cathode electrode 23 may be arranged and extending to cover the organic light emitting layer 22 of each of the plurality of light emitting units 2. The one integral cathode electrode 23 forms one integral common cathode. The one integral common cathode has a plurality of portions disposed corresponding to the plurality of light emitting units 2, such that each of the plurality of portions serves as the cathode electrode 23 for a respective one of the plurality of light emitting units 2. The anode electrode 21 and the cathode electrode 23 may transmit an anode drive signal and a cathode drive signal, respectively, to the organic light emitting layer 22 to drive the organic light emitting layer 22 to emit light.

In some embodiments, the plurality of light emitting units 2 may include light emitting units 2 that emit light in different colors, such as a red light emitting unit, a green light emitting unit, and a blue light emitting unit, such that colorful displaying may be achieved. Specifically, a light color of each light emitting unit 2 may be determined by a light color of the organic light emitting layer 22. Alternatively, in some embodiments, the plurality of light emitting units 2 may emit light in one same color, such as white, red, green, blue, or any other color, which may be determined according to the actual needs. For example, the light emitting unit 2 may emit light in white, and brightness of the light emitting unit 2 may be adjusted to achieve grayscale displaying. A color resistant layer may be arranged on top of the light emitting unit 2 to achieve the colorful displaying. For example, the plurality of light emitting units 2 may emit light in blue, and a red quantum dot layer may be arranged above a portion of the plurality of light emitting units 2, and a green quantum dot layer may be arranged above another portion of the light emitting units 2, such that the colorful displaying may be achieved.

The plurality of bonding portions 4 are arranged on the second surface 12 of the glass substrate 1. Each of the plurality of bonding portions 4 may be electrically connected to the anode electrode 21 through a respective one of the plurality of first conductive through hole 131 to transmit the anode drive signal to the anode electrode 21 of a respective one of the plurality of light emitting units 2 through the respective first conductive through hole 131.

The silicon-based driver substrate 5 is arranged on the second surface 12 of the glass substrate 1. The silicon-based driver substrate 5 may further include a plurality of bonding electrodes 51. The plurality of bonding electrodes 51 and the plurality of bonding portions 4 are in one-to-one correspondence to each other to control the plurality of light emitting units 2 corresponding to the plurality of bonding portions 4 to emit light. Specifically, the silicon-based driver substrate 5 may further include a monocrystalline silicon substrate 53 and a driver circuit 54 stacked on the monocrystalline silicon substrate 53. The driver circuit 54 may be electrically connected to the plurality of bonding electrodes 51 to transmit the anode drive signal to the anode electrode 21 through the respective bonding portion 4. Specifically, the driver circuit 54 may include a plurality of “3TIC” structures (three thin-film transistors and one capacitor) to independently control each of the plurality of light emitting units 2 to achieve high-quality displaying.

The silicon-based driver substrate 5 may further include a display control circuit (not shown) electrically connected to the driver circuit 54. The display control circuit may control, through the driver circuit 54, the plurality of light emitting units 2 to display contents. The display control circuit may be an integrated circuit (IC) integrated on the silicon-based driver substrate 5.

By arranging the plurality of light emitting units 2 and the plurality of bonding portions 4 respectively on two opposite surfaces of the glass substrate 1, each of the plurality of bonding portions 4 may be electrically connected, through the respective one of the plurality of first conductive through holes 131, to the anode electrode 21 of the respective one of the plurality of light emitting units 2. In this way, after the bonding portions 4 are bonded with the bonding electrodes 51 of the silicon-based driver substrate 5, the plurality of light emitting units 2 may be electrically coupled with the silicon-based driver substrate 5, such that the silicon-based driver substrate 5 may drive the plurality of light emitting units 2 to emit light. In this way, the plurality of light emitting units 2 may be prepared on the glass substrate 1 firstly, and subsequently, the plurality of light emitting units 2 may be bonded to the silicon-based driver substrate 5. Damage to the pixel driver circuit 54, which may be caused by directly preparing the plurality of light emitting units 2 on the silicon-based driver substrate 5, may be avoided, and a product yield may not be reduced.

As shown in FIG. 2a, each of the plurality of bonding portions 4 has a first snap portion 41, and each of the plurality of bonding electrodes 51 has a second snap portion 511. One of the first snap portion 41 and the second snap portion 511 may be a recessed structure; and the other one of the first snap portion 41 and the second snap portion 511 may be a protruding structure. The protruding structure may be embedded in the recessed structure. In the present embodiment, the first snap portion 41 of the bonding portion 4 may be the recessed structure, and the second snap portion 511 of the bonding electrode 51 may be the protruding structure. The second snap portion 511 may be embedded in the first snap portion 41 to enable the bonding electrode 51 to be aligned to and bonded with the bonding portion 4. Specifically, as shown in FIGS. 2a and 2b, the second snap portion 511 may include a protruding portion 5111, and the first snap portion 41 may include a recessed structure 411. The protruding portion 5111 may be embedded in the recessed structure 411 to enable the first snap portion 41 to be aligned to and bonded with the second snap portion 511.

Of course, in other embodiments, the first snap portion 41 may be the protruding structure, and the second snap portion 511 may be the recessed structure, and the first snap portion 41 may be embedded in the second snap portion 511 to enable the bonding portion 4 to be aligned to and bonded with the bonding electrode 51.

By arranging one of the first snap portion 41 and the second snap portion 511 as the recessed structure and the other one of the first snap portion 41 and the second snap portion 511 as the protruding structure, and by embedding the protruding structure in the recessed structure, a bonding contact area between the bonding portion 4 and the bonding electrode 51; may be increased. In this way, a contact resistance may be reduced, and a signal transmission efficiency between each bonding electrode 51 of the silicon-based driver substrate 5 and the anode electrode 21 of the respective light emitting unit 2 may be improved. In addition, embedding between the first snap portion 41 and the second snap portion 511 may prevent relative displacement between the glass substrate 1 and the silicon-based driver substrate 5, such that the contact resistance may not be affected. Furthermore, the embedding may improve the extent of bonding between the glass substrate 1 and the silicon-based driver substrate 5, preventing an influence in the contact resistance caused by unstable bonding.

As shown in FIG. 1a, in an embodiment, the silicon-based driver substrate 5 may further include a plurality of connection electrodes 52. The plurality of conductive through holes 13 may further include a plurality of second conductive through holes 132. Each of the plurality of second conductive through holes 132 may be filled with metal. The cathode electrode 23 may be electrically connected to the metal filled in each of the plurality of second conductive through holes 132. In this way, the silicon-based driver substrate 5 may transmit the cathode drive signal to the cathode electrode 23 through the plurality of connection electrodes 52 and the metal filled in the plurality of second conductive through holes 132. It is noted that the metal filled in each of the plurality of second conductive through holes 132 may at least partially protrude out of a respective one of the plurality of second conductive through holes 132 to contact a respective one of the plurality of connection electrodes 52.

Specifically, the plurality of connection electrodes 52 may be electrically connected to the driver circuit 54. The display control circuit of the silicon-based driver substrate 5 may transmit, through the driver circuit 54, the cathode drive signal to the plurality of connection electrodes 52. The silicon-based driver substrate 5 may be spaced apart from the glass substrate 1, and the metal filled in each of the plurality of second conductive through holes 132 may extend from the second surface 12 of the glass substrate 1 toward the glass substrate 1 to be in contact with the respective one of the plurality of connection electrodes 52.

Further, as shown in FIG. 1a, FIG. 2a and FIG. 2b, the metal filled in each of the plurality of second conductive through holes 132 may include the first snap portion 41, and the respective connection electrode 52 may have the second snap portion 511. It is understood that the first snap portion 41 of the metal filled in each of the plurality of second conductive through holes 132 may have the same structure as that of the bonding portion 4; and the second snap portion 511 of each of the plurality of connection electrodes 52 may have the same structure as that of the bonding electrode 51. The first snap portion 41 and the second snap portion 511 may be embeddedly connected to each other to increase a contact area between the metal filled in each second conductive through hole 132 and the respective connection electrode 52. In this way, a contact resistance may be reduced, and a signal transmission efficiency between each of the plurality of connection electrodes 52 of the silicon-based driver substrate 5 and the cathode electrode 23 of the respective one of the plurality of light emitting units 2 may be effectively improved. In addition, the embedding may prevent relative displacement between the glass substrate 1 and the silicon-based driver substrate 5, such that the contact resistance may not be affected. Specifically, an end of the metal filled in each second conductive through hole 132 near the respective connection electrode 52 may have a recessed structure 411, and an end of each connection electrode 52 near the respective second conductive through hole 132 may have a protruding portion 5111. The protruding portion 5111 may be embedded in the recessed structure 411.

In an embodiment, as shown in FIG. 1a, the silicon-based driver substrate 5 may further include a protective layer 55 to protect the driver circuit 54. The protective layer 55 may be disposed on a side of the driver circuit 54 away from the monocrystalline silicon substrate 53. The protective layer 55 may define a plurality of via holes. Each of the plurality of via holes may extend through the protective layer 55. The plurality of bonding electrodes 51 may be respectively received in a portion of the plurality of via holes to electrically connect the driver circuit 54 with the plurality of bonding portions 4. The plurality of connection electrodes 52 may be respectively received in another portion of the plurality of via holes to electrically connect the driver circuit 54 and the metal filled in the plurality of second conductive through holes 132. The protective layer 55 may specifically be made of an inorganic insulating material, such as silicon dioxide, silicon nitride, or silicon nitride oxide.

As shown in FIG. 1a, an encapsulation layer 24 may be arranged on the glass substrate 1 to protect the plurality of light emitting units 2 on the glass substrate 1, isolating external water and oxygen from the plurality of light emitting units 2, and avoiding invasion of the water and the oxygen from leading to failure of the plurality of light emitting units 2. Specifically, the encapsulation layer 24 may cover a side surface of the cathode electrode 23 away from the anode electrode 21 and may lap over a surface of the glass substrate 1 that is not covered by the plurality of light emitting units 2.

As shown in FIG. 1b, in some embodiments, the encapsulation layer 24 may extend to reach the silicon-based driver substrate 5 to seal a gap between the silicon-based driver substrate 5 and the glass substrate 1, so as to isolate the external water and oxygen and to avoid the water and the oxygen from invading to corrode the bonding portions 4 and the bonding electrodes 51, such that failure of bonding between the bonding portions 4 and the bonding electrodes 51 may be prevented. Specifically, in the above embodiments, along a stacking direction, a projection of the glass substrate 1 onto the silicon-based driver substrate 5 may be located inside the silicon-based driver substrate 5, and a circumferential edge of the silicon-based driver substrate 5 may protrude out of the glass substrate 1. The encapsulation layer 24 may cover the side of the cathode electrode 23 away from the anode electrode 21 and may lap over the surface of the glass substrate 1 that is not covered by the plurality of light emitting units 2. The encapsulation layer 24 may extend along a side of the glass substrate 1 from the first surface 11 to a side surface of the protective layer 55 away from the monocrystalline silicon substrate 53.

As shown in FIG. 1c, in other embodiments, the silicon-based driver substrate 5 may further include an insulating layer 56 to protect the plurality of bonding portions 4 and the metal filled in the plurality of second conductive through holes 132. The insulating layer 56 may be arranged on a side surface of the protective layer 55 away from the monocrystalline silicon substrate 53. A side surface of the insulating layer 56 away from the protective layer 55 may be arranged on the second surface of the glass substrate 1. The insulating layer 56 defines a plurality of openings. A portion of the plurality of openings may be in one-to-one correspondence with the plurality of first conductive through holes 131 to receive portions of the plurality of bonding portions 4 disposed outside of the plurality of first conductive through holes 131. Another portion of the plurality of openings may be in one-to-one correspondence with the plurality of second conductive through holes 132 to receive portions of the metal filled in the plurality of second conductive through holes 132 protruding from the plurality of second conductive through holes 132.

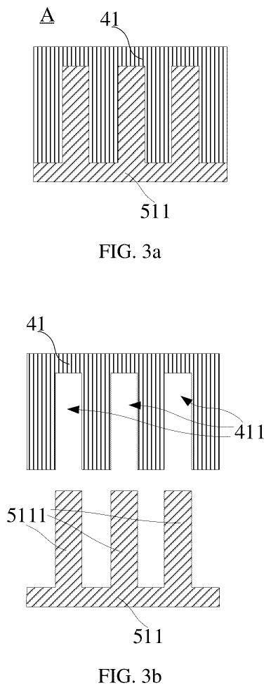

As shown in FIGS. 3a and 3b, FIG. 3a is an enlarged view of a portion A in the display panel according to a second embodiment of the present disclosure; and FIG. 3b is an exploded view of the portion A shown in FIG. 3a. A structure of the display panel provided in the second embodiment may be substantially the same as that in the first embodiment of the present disclosure. In the present embodiment, the protruding structure may include a plurality of protruding portions 5111 that are spaced apart from each other. The recessed structure may include a plurality of recesses 411 that are spaced apart from each other. Each of the plurality of protruding portions 5111 is embedded in a respective one of the plurality of recesses 411, such that the bonding contact area between the bonding portions 4 and the bonding electrodes 51 may be increased, further reducing the contact resistance. In addition, by arranging the plurality of protruding portions 5111 and the plurality of recesses 411 in which the plurality of protruding portions 5111 may be embedded, bonding stability between the bonding electrodes 51 and the bonding portions 4 may be further improved.

Specifically, the plurality of protruding portions 5111 may be spaced apart from each other and may be in parallel to each other. Accordingly, the plurality of recesses 411 may be spaced apart from each other and may be in parallel to each other. In this way, the plurality of protruding portions 5111 and the plurality of recesses 411 may be arranged regularly, enabling the plurality of protruding portions 5111 to be easily aligned to and bonded with the plurality of recesses 411. The plurality of recesses 411 may be disposed at an equal interval and may have a same shape and a same size. A width of each of the plurality of recesses 411 may be equal to a spacing between two adjacent recesses 411 of the plurality of recesses 411. Correspondingly, the plurality of protruding portions 5111 may be disposed at an equal interval and may have a same shape and a same size. A width of each of the plurality of protruding portions 5111 may be equal to a spacing between two adjacent protruding portions 5111 of the plurality of protruding portions 5111. The shape of each protruding portion 5111 and the shape of each recess 411 may both be rectangular or square.

It can be understood that a side wall between the two adjacent recesses 411 of the first snap portion 41 may also form one protruding portion 5111, and the two adjacent protruding portions 5111 of the second snap portion 511 may form one recess 411. That is, in the present embodiment, each of the first snap portion 41 and the second snap portion 511 may have the plurality of recesses 411 and the plurality of protruding portions 5111. The plurality of protruding portions 5111 of the first snap portion 41 may be embedded in the plurality of recesses 411 of the second snap portion 511; and the plurality of protruding portions 5111 of the second snap portion 511 may be embedded in the plurality of recesses 411 of the first snap portion 41. In this way, the first snap portion 41 and the second snap portion 511 may be mutually embedded in each other.

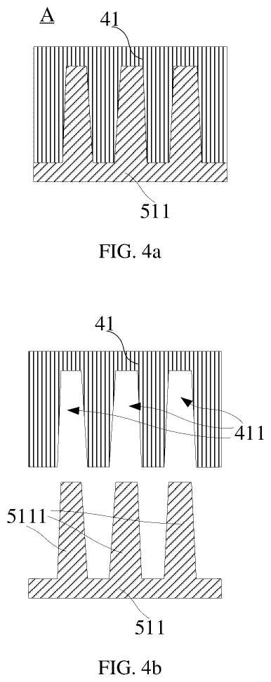

As shown in FIG. 4a and FIG. 4b, FIG. 4a is an enlarged view of a portion A in the display panel according to a third embodiment of the present disclosure; and FIG. 4b is an exploded view of the portion A shown in FIG. 4a. A structure of the display panel provided in the third embodiment may be substantially the same as that in the second embodiment of the present disclosure. In the third embodiment of the present disclosure, each of two ends of the recessed structure 411 may be an open-ended structure, facilitating the plurality of protruding portions 5111 to be embedded in the recessed structure 411, such that difficulty of bonding may be reduced.

Specifically, along a direction in which the glass substrate 1 faces towards the silicon-based driver substrate 5, the width of each of the plurality of recesses 411 of the first snap portion 41 gradually increases, and an angle between each of two side walls of each recess 411 and a bottom wall of the recess 411 may be greater than 90° to form the open-ended structure. Correspondingly, along a direction in which the silicon-based driver substrate 5 faces towards the glass substrate 1, the width of each protruding portion 5111 on the second snap portion 511 gradually decreases, and an angle between two side walls of the protruding portion 5111 and a top wall of the protruding portion 5111 may be greater than 90° to form an upright-disposed trapezoidal structure. The two side walls of the protruding portion 5111 may be in contact with the two side walls of the recess 411, respectively, and the top wall of the protruding portion 5111 may abut against the bottom wall of the recess 411.

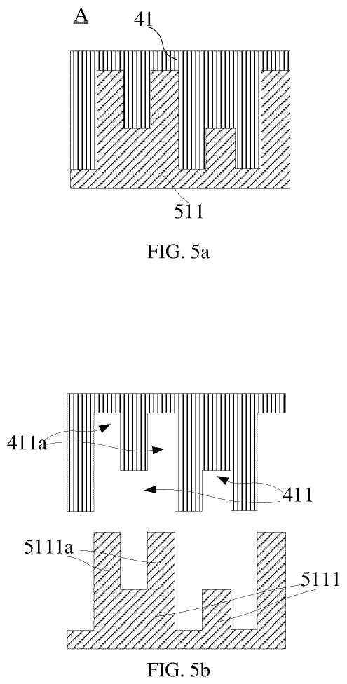

As shown in FIG. 5a and FIG. 5b, FIG. 5a is an enlarged view of a portion A in the display panel according to a fourth embodiment of the present disclosure; and FIG. 5b is an exploded view of the portion A shown in FIG. 5a. A structure of the display panel provided in the fourth embodiment may be substantially the same as that in the second embodiment of the present disclosure. In the fourth embodiment, for at least one of the plurality of protruding portions 5111, a sub-protruding portion 5111a may be arranged on a top of the protruding portion 5111; and for at least one of the plurality of recesses 411, a sub-recess 411a may be defined at the bottom of the recess 411. The sub-protruding portion 5111a may be embedded in the sub-recess 411a to further increase the bonding contact area between the bonding portions 4 and the bonding electrodes 51, such that the contact resistance may be further reduced; and to further improve the bonding stability between the bonding electrodes 51 and the bonding portions 4.

Specifically, two adjacent protruding portions 5111 of the plurality of protruding portions 5111 may have different shapes and sizes, and a width of one of the two adjacent protruding portions 5111 may be greater than a width of the other one of the two adjacent protruding portions 5111. At least one sub-protruding portion 5111a may be arranged at a top of the protruding portion 5111 having the greater width, and the sub-protruding portion 5111a may extend towards the recessed structure 411. Correspondingly, two adjacent recesses 411 of the plurality of recesses 411 may have different shapes and sizes. A width of one of the two adjacent recesses 411 may be greater than a width of the other one of the two adjacent recesses 411. The recess 411 having the greater width may be disposed in correspondence with the protruding portion 5111 having the greater width; and the recess 411 having the smaller width may be disposed in correspondence with the protruding portion 5111 having the smaller width. A surface of the bottom of a portion of the recess 411 having the larger width may extend away from the protruding portion 5111 to form at least one sub-recess 411a. In some embodiments, a plurality of sub-protruding portions 5111a may be arranged on each protruding portion 5111 having the larger width, and a plurality of sub-recesses 411a may be defined in each recess 411 having the larger width.

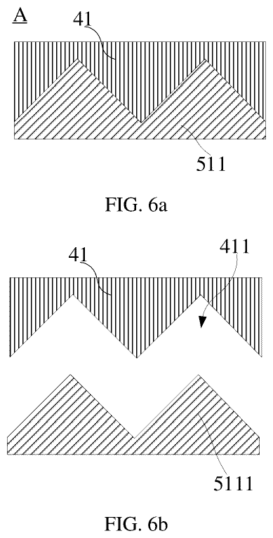

As shown in FIG. 6a and FIG. 6b, FIG. 6a is an enlarged view of a portion A in the display panel according to a fifth embodiment of the present disclosure; and FIG. 6b is an exploded view of the portion A shown in FIG. 6a. A structure of the display panel provided in the fifth embodiment may be substantially the same as that provided in the second embodiment of the present disclosure. In the fifth embodiment of the present disclosure, along a direction perpendicular to the glass substrate 1, a cross section of each protruding portion 5111 and a cross section of each recess 411 may both be triangular in shape, so as to further increase the bonding contact area between the bonding portion 4 and the bonding electrode 51, such that the contact resistance may be further reduced. In addition, embedding the protruding portion 5111 into the recess 411 may further be facilitated, so as to minimize difficulty of bonding.

Specifically, along the direction in which the glass substrate 1 face towards the silicon-based driver substrate 5, the width of the recess 411 of the first snap portion 41 gradually increases, such that a triangular recess may be formed. Correspondingly, along the direction in which the silicon-based driver substrate 5 faces towards the glass substrate 1, the width of the protruding portion 5111 of the second snap portion 511 gradually decreases, such that a triangular protruding portion 5111 may be formed. The two side walls of the protruding portion 5111 may be respectively in contact with the two side walls of the recess 411. A top end of the protruding portion 5111 may abut against a bottom end of the recess 411. Each of the shape of the protruding portion 5111 and the shape of the recess 411 may be any one of: a cone, a polygonal pyramid, or a triangular prism.

The present disclosure provides the display panel includes the glass substrate 1, the plurality of light emitting units 2, the plurality of bonding portions 4, and the silicon-based driver substrate 5. By arranging the light emitting units 2 and the bonding portions 4 respectively on two opposite surfaces of the glass substrate 1, each of the plurality of bonding portions 4 is electrically connected to the anode electrode 21 of the respective one of the plurality of light emitting units 2 through the respective one of the plurality of first conductive through holes 131. In this way, after the bonding portions 4 are bonded to the bonding electrodes 51 of the silicon-based driver substrate 5, the light emitting units 2 may be electrically coupled to the silicon-based driver substrate 5, such that the silicon-based driver substrate 5 may drive the light emitting units 2 to emit light. In this way, the light emitting units 2 may be prepared on the glass substrate 1 firstly, and subsequently, the light emitting units 2 may be bonded to the silicon-based driver substrate 5, such that the light emitting units 2 may not be directly prepared on the silicon-based driver substrate 5, and any damage to the pixel driver circuit 54, which may be caused by directly preparing the light emitting units 2 on the silicon-based driver substrate 5, may be avoided, and a product yield may not be affected. Further, by arranging one of the first snap portion 41 and the second snap portion 42 as the recessed structure and arranging the other one of the first snap portion 41 and the second snap portion 42 as the protruding structure, and by embedding the protruding structure in the recessed structure, a bonding contact area between the bonding portion 4 and the bonding electrode 51 may be increased, and the contact resistance is reduced. Therefore, the signal transmission efficiency between the bonding electrodes 51 of the silicon-based driver substrate 5 and the anode electrodes 21 of the light emitting units 2 may be effectively improved. In addition, embedding of the first snap portion 41 and the second snap portion 42 may prevent relative displacement between the glass substrate 1 and the silicon-based driver substrate 5, such that the contact resistance may not be affected. Furthermore, the embedding may improve an extent of bonding between the glass substrate 1 and the silicon-based driver substrate 5, such that the contact resistance may not be affected due to unstable bonding therebetween.

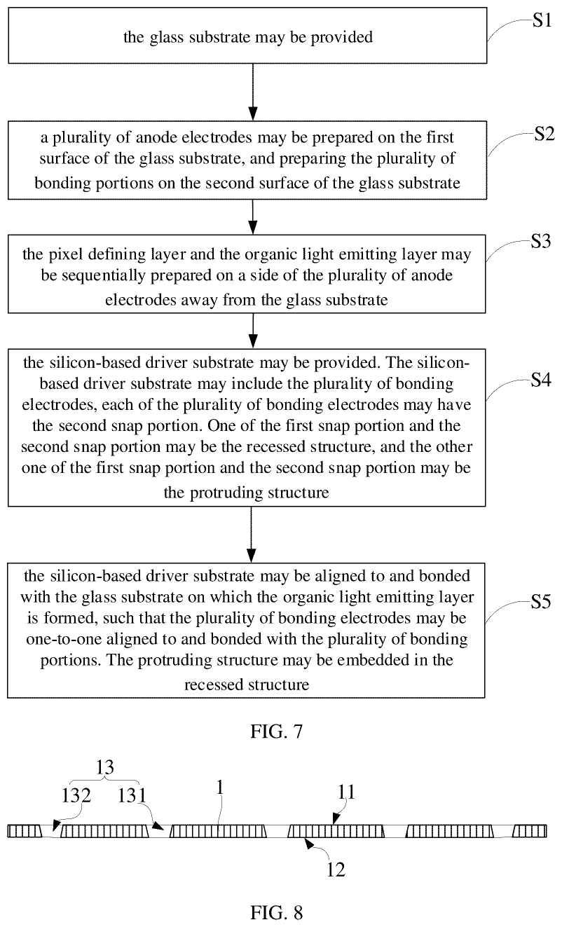

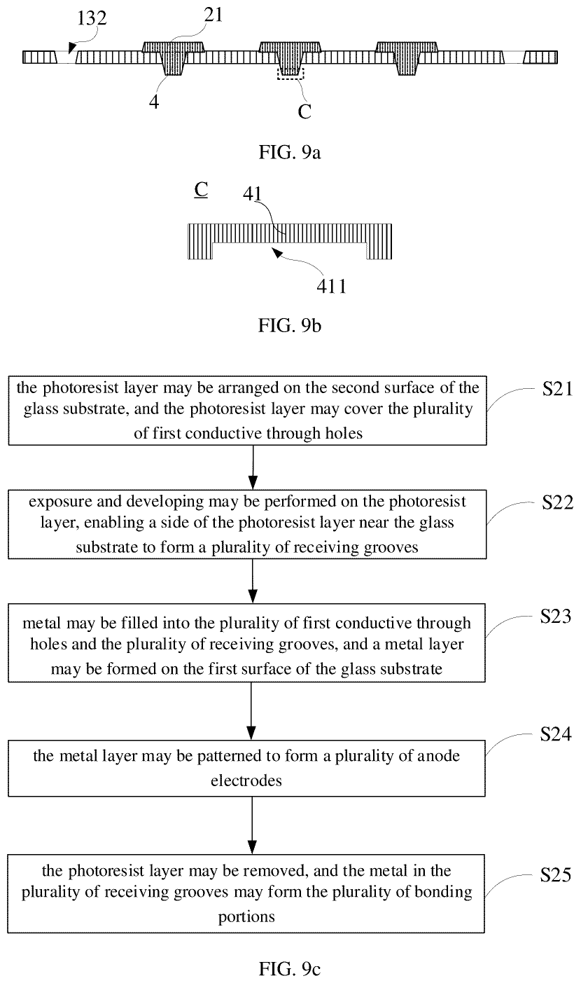

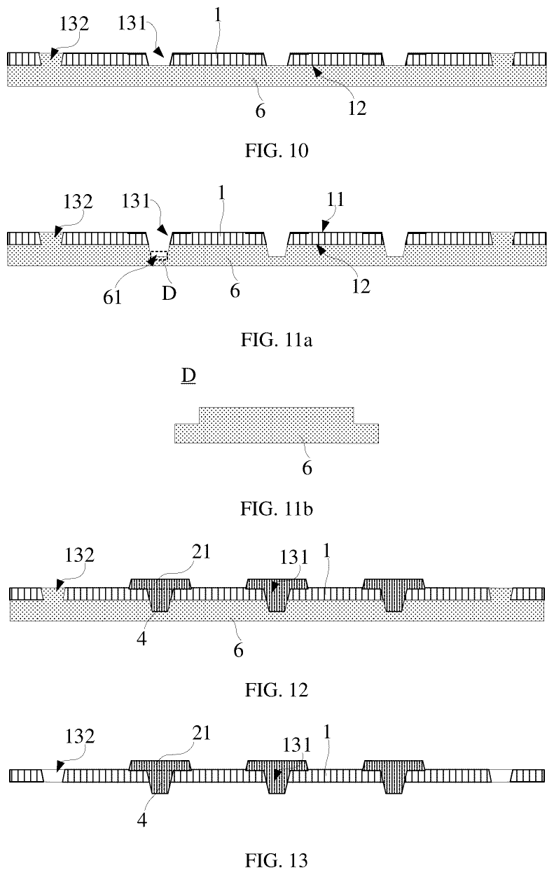

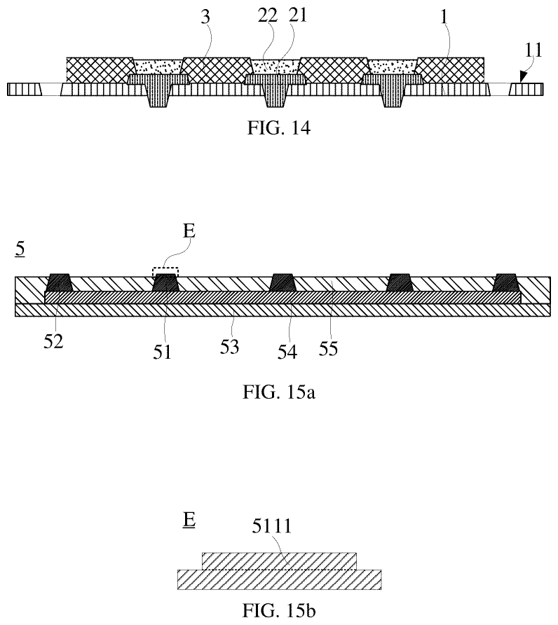

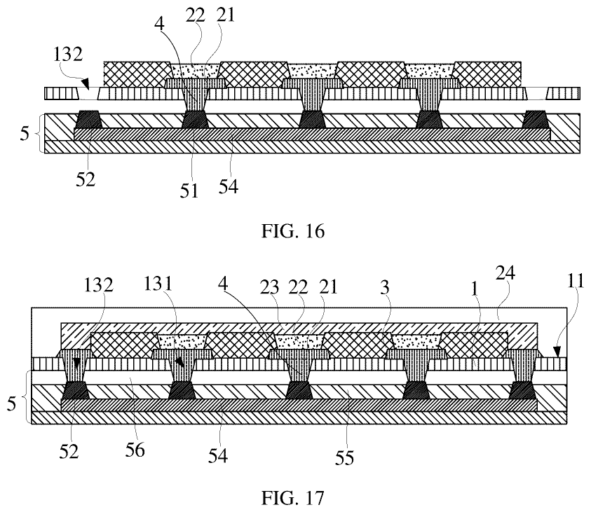

As shown in FIGS. 7 to 17, FIG. 7 is a flow chart of a method of manufacturing the display panel according to an embodiment of the present disclosure; FIG. 8 is a structural schematic view of a structure obtained after performing the operation S1; FIG. 9a is a structural schematic view of a structure obtained after performing the operation S2; FIG. 9b is an enlarged view of a portion C in the structure shown in FIG. 9a; FIG. 9c is a flow chart of performing the operation S2; FIG. 10 is a structural schematic view of a structure obtained after performing the operation S21; FIG. 11a is a structural schematic view of a structure obtained after performing the operation S22; FIG. 11b is an enlarged view of a portion D in the structure shown in FIG. 11a; FIG. 12 is a structural schematic view of a structure obtained after performing the operations S23 and S24; FIG. 13 is a structural schematic view of a structure obtained after performing the operation S25; FIG. 14 is a structural schematic view of a structure obtained after performing the operation S3; FIG. 15a is a structural schematic view of a structure obtained after performing the operation S4; FIG. 15b is an enlarged view of a portion E in the structure shown in FIG. 15a; FIG. 16 is a structural schematic view of a structure obtained after performing the operation S5; FIG. 17 is a structural schematic view of a cathode electrode, which is electrically connected to a connection electrode and is arranged on the structure shown in FIG. 16. As shown in FIG. 7, the method may specifically include following operations.

In an operation S1, the glass substrate may be provided.

Specifically, as shown in FIG. 8, the glass substrate 1 may include the first surface 11 and the second surface 12 opposite to the first surface 11. Specifically, a surface located on a light output side of the display panel may be the first surface 11, and the other surface opposite to the first surface 11 may be the second surface 12. The glass substrate 1 may have the plurality of conductive through holes 13 extending from the first surface 11 to the second surface 12. In an embodiment, a laser-induced etching operation may be performed to form the plurality of conductive through holes 13 in the glass substrate 1. The diameter of each of the plurality of conductive through holes 13 may be in the range of 50 μm to 100 μm.

Specifically, locations on the glass substrate 1 where the plurality of conductive through holes are to be formed may be firstly irradiated by laser to form a modified region. Subsequently, an etching solution may be applied to etch the modified region to form the plurality of conductive through holes 13. Compared to the monocrystalline silicon substrate 53, the glass substrate 1 may have better insulating performance, and therefore, an oxidation insulating layer does not need to be prepared on a hole wall of the conductive through hole 13, and a specialized technique for carrying thin wafers may not be performed, such that manufacturing costs may be reduced. At the same time, due to the better insulating performance of the glass substrate 1, during transmitting signals, electromagnetic coupling effects may not be generated, insertion loss of signals may be reduced, signal crosstalk may be reduced, and integrity of signals may be ensured.

In an operation S2, a plurality of anode electrodes may be prepared on the first surface of the glass substrate, and preparing the plurality of bonding portions on the second surface of the glass substrate.

Specifically, as shown in FIG. 9a, each bonding portion 4 may be electrically connected to the respective anode electrode 21 through the respective conductive through hole 13. The anode electrode 21 is configured to transmit the anode drive signal to the organic light emitting layer 22 to drive the organic light emitting layer 22 to emit light. The bonding portions 4 may be configured to be aligning to and bonding with the bonding electrodes 51 of the silicon-based driver substrate 5 to enable the anode drive signal to be transmitted through the bonding portions 4 to the anode electrode 21. Specifically, each bonding portion 4 may extend along the respective conductive through hole 13 to be in contact with the respective anode electrode 21. As shown in FIG. 9b, an end of each bonding portion 4 away from the anode electrode 21 may have the first snap portion 41.

Specifically, as shown in FIG. 8 and FIG. 9a, the plurality of conductive through holes 13 may include the plurality of first conductive through holes 131 and the plurality of second conductive through holes 132. The plurality of bonding portions 4 may be in one-to-one correspondence with the plurality of first conductive through holes 131. As shown in FIG. 9c, in an embodiment, the operation S2 may specifically include following operations.

In an operation S21, the photoresist layer may be arranged on the second surface of the glass substrate, and the photoresist layer may cover the plurality of first conductive through holes.

Specifically, as shown in FIG. 10, the photoresist layer 6 may be coated on the second surface 12 of the glass substrate 1 and may fully fill the plurality of conductive through holes 13. Furthermore, a portion of the photoresist layer 6 inside the plurality of first conductive through holes 131 may be removed by mask exposure, and another portion of the photoresist layer 6 arranged in the plurality of second conductive through holes 132 may be retained. In this way, when filling the metal in the plurality of first conductive through holes 131 at subsequently operations, the metal may be prevented from being deposited in the plurality of second conductive through holes 132.

In an operation S22, exposure and developing may be performed on the photoresist layer, enabling a side of the photoresist layer near the glass substrate to form a plurality of receiving grooves.

Specifically, as shown in FIG. 11a, a mask (not shown) may be arranged on the first surface 11 of the glass substrate 1 to cover the plurality of second conductive through holes 132; and the exposure and developing may be performed, from a side of the first surface 11, on a portion of the photoresist layer 6 exposed through the plurality of first conductive through holes 131 to form the plurality of receiving grooves 61 that may be in one-to-one correspondingly communication with the plurality of first conductive through holes 131, and the plurality of bonding portions 4 may be prepared in the plurality of receiving grooves 61. Specifically, as shown in FIG. 11b, a bottom of each of the plurality of receiving grooves 61 may have a concave-convex structure configured to prepare the first snap portion 41. It is understood that a shape of the concave-convex structure may be complementary to a shape of the first snap portion 41. When the first snap portion 41 is the recessed structure, the bottom of the receiving groove 61 may be a convex structure; and when the first snap portion 41 is the protruding structure, the bottom of the receiving groove 61 may be a concave structure.

In an operation S23, metal may be filled into the plurality of first conductive through holes and the plurality of receiving grooves, and a metal layer may be formed on the first surface of the glass substrate.

Specifically, the metal may be deposited into the plurality of first conductive through holes 131 and the corresponding plurality of receiving grooves 61 from a side of the first surface 11 of the glass substrate 1, the metal may be deposited on the first surface 11 of the glass substrate 1 to form the metal layer (not shown in the figure). The metal layer may cover the plurality of first conductive through holes 131 and expose the plurality of second conductive through holes 132.

In an operation S24, the metal layer may be patterned to form a plurality of anode electrodes.

Specifically, as shown in FIG. 12, the metal layer of the first surface 11 may be patterned by mask etching, and a portion of the metal layer corresponding to the plurality of first conductive through holes 131 may be retained to form the plurality of anode electrodes 21 that are spaced apart from each other. Along the stack direction, a projection of each of the plurality of first conductive through holes 131 on the glass substrate 1 may be located within a projection of a respective one of the plurality of anode electrodes 21 on the glass substrate 1, and that is, each anode electrode 21 may completely cover the respective first conductive through hole 131.

In an operation S25, the photoresist layer may be removed, and the metal in the plurality of receiving grooves may form the plurality of bonding portions.

Specifically, as shown in FIG. 13, the photoresist layer 6 on the second surface 12 of the glass substrate 1 may be removed by exposure to expose the metal inside the plurality of receiving grooves 61 to form the plurality of bonding portions 4. Each of the plurality of bonding portions 4 may extend from a side surface of the respective anode electrode 21 facing the glass substrate 1 along the respective first conductive through hole 131 to the second surface 12 of the glass substrate 1 and may protrude out of the second surface 12. Meanwhile, exposure may be performed to remove the photoresist layer 6 arranged inside the plurality of second conductive through holes 132 to expose the plurality of second conductive through holes 132.

In an operation S3, the pixel defining layer and the organic light emitting layer may be sequentially prepared on a side of the plurality of anode electrodes away from the glass substrate.

Specifically, as shown in FIG. 14, the photoresist may be patterned to form the pixel definition layer 3 on the first surface 11 of the glass substrate 1. Alternatively, an inorganic material film may be patterned to form the pixel definition layer 3. The formation may be determined according to the actual need. The pixel defining layer 3 may protrude from the glass substrate 1 and form a plurality of pixel receiving regions. The pixel defining layer 3 may cover edges of the anode electrodes 21 to ensure that adjacent anode electrodes 21 are not in contact with each other. A portion of a surface of the anode electrode 21 may be exposed through the pixel receiving region, such that the organic light emitting layer 22 may be prepared on the surface of the anode electrode 21 located in the pixel receiving region.

Different light emitting layer materials may be used for evaporation to form the organic light emitting layers 22 in different colors, such as a red light emitting layer, a green light emitting layer, and a blue light emitting layer, on the surfaces of the plurality of anode electrodes 21. Alternatively, a white light emitting layer material may be used for evaporation to form a white light emitting layer; and a color filtering layer may be subsequently prepared to achieve colorful displaying.

In an operation S4, the silicon-based driver substrate may be provided. The silicon-based driver substrate may include the plurality of bonding electrodes, each of the plurality of bonding electrodes may have the second snap portion. One of the first snap portion and the second snap portion may be the recessed structure, and the other one of the first snap portion and the second snap portion may be the protruding structure.

Specifically, as shown in FIG. 15a, by preparing the drive circuit 54 on the monocrystalline silicon substrate 53, the light emitting units 2 and the silicon-based drive substrate 5 may be prepared independent from each other. In this way, a production efficiency may be improved. Moreover, by taking the monocrystalline silicon substrate 53 as the substrate for the silicon-based driver substrate 5, advantages of the silicon-based driver substrate 5 may be retained. In addition, by taking the glass substrate 1 as the substrate for the light emitting units 2, the manufacturing costs can be saved. Stability of the glass substrate 1 may be better, the glass substrate 1 may not be easily deformed due to temperatures, such that stability and electrical performance of the light emitting device may be maintained. The glass substrate 1 may have better light transmittance performance, such that brightness of the display panel may be improved. Further, by preparing the light emitting units 2 on the glass substrate 1, a large-size display panel may be obtained.

A conductive material may be deposited and patterned on a side surface of the driver circuit 54 away from the monocrystalline silicon substrate 53 to form the plurality of bonding electrodes 51. As shown in FIGS. 9b with FIGS. 15b, in the present embodiment, the first snap portion 41 of the bonding portion 4 may be the recessed structure, and the second snap portion 511 of the bonding electrode 51 may be the protruding structure. That is, the first snap portion 41 may have the recess 411, and the second snap portion 511 may have the protruding portion 5111. The protruding portion 5111 may be formed, by mask etching, at the end of the second snap portion 511 away from the drive circuit 54. In this way, by arranging one of the first snap portion 41 and the second snap portion 511 as the recessed structure and the other one of the first snap portion 41 and the second snap portion 511 as the protruding structure, and by embedding the protruding structure in the recessed structure, the bonding contact area between the bonding portion 4 and the bonding electrode 51 may be increased. In this way, the contact resistance may be reduced, and the signal transmission efficiency between the bonding electrodes 51 of the silicon-based driver substrate 5 and the anode electrodes 21 of the light emitting units 2 may be improved.

Further, an insulating material may be deposited on the side surface of the drive circuit 54 away from the monocrystalline silicon substrate 53 to form the protective layer 55 to protect the driver circuit 54. The second snap portion 511 may be exposed from the protective layer 55, facilitating the second snap portion 511 and the first snap portion 41 to be embeddedly connected to each other.

In an operation S5, the silicon-based driver substrate may be aligned to and bonded with the glass substrate on which the organic light emitting layer is formed, such that the plurality of bonding electrodes may be one-to-one aligned to and bonded with the plurality of bonding portions. The protruding structure may be embedded in the recessed structure.

Specifically, as shown in FIG. 16, the plurality of bonding electrodes 51 may be one-to-one bonded with the plurality of bonding portions 4, such that the anode drive signal of the silicon-based driver substrate 5 may be transmitted, through the bonding electrodes 51 and the bonding portions 4, to the anode electrodes 21 of the light emitting units 2 to drive the organic light emitting layer 22 to emit light.

As shown in FIG. 16, the silicon-based driver substrate 5 may further include a plurality of connection electrodes 52, the plurality of connection electrodes 52 may be electrically connected to the driver circuit 54, and the plurality of connection electrodes 52 may be disposed in one-to-one alignment with the plurality of second conductive through holes 132. In an embodiment, after the operation S5, the method may further include: filling metal in the plurality of second conductive through holes, enabling the metal filled in the plurality of second conductive through holes to be electrically connected to the plurality of connection electrodes.

Specifically, as shown in FIG. 17, the mask may be applied to expose the plurality of second conductive through holes 132, and the metal may be deposited from a side of the first surface 11 of the glass substrate 1 towards the plurality of second conductive through holes 132. The metal may fully fill the plurality of second conductive through holes 132 and may further extend toward the silicon-based driver substrate 5 to be in contact with the plurality of connection electrodes 52. In this way, the silicon-based driver substrate 5 may transmit, through the plurality of connection electrodes 52, the cathode drive signal to the metal filled in the plurality of second conductive through holes 132.

Specifically, the insulating layer 56 may be arranged the side surface of the protective layer 55 away from the monocrystalline silicon substrate 53. The insulating layer 56 may define the plurality of openings. When the silicon-based driver substrate 5 is aligned to and bonded with the glass substrate 1, a portion of the plurality of openings may be in one-to-one correspondence with the plurality of first conductive through holes 131, and the plurality of bonding portions 4 may be embedded in the portion of the plurality of openings corresponding to the plurality of first conductive through holes 131. Another portion of the plurality of openings may be in one-to-one correspondence with the plurality of second conductive through holes 132 and may expose the plurality of connection electrodes 52. In this way, it is ensured that, when depositing the metal into the plurality of second conductive through holes 132, the metal may be in contact with the plurality of connection electrodes 52 and sequentially fill the another portion of the plurality of openings corresponding to the plurality of second conductive through holes 132 and the plurality of second conductive through holes 132.

After filling the plurality of second conductive through holes 132 with metal, the method may further include: preparing the cathode electrode on the side of the organic light emitting layer away from the glass substrate, enabling the cathode electrode to be electrically connected to the metal filled in the plurality of second conductive through holes.

As shown in FIG. 17, in an embodiment, a cathode material may be deposited, by evaporation or sputtering, on the side of the organic light emitting layer 22 away from the glass substrate 1 to form the cathode electrode 23. In some embodiments, the cathode material may be deposited by magnetron sputtering to prevent the driver circuit 54 from being damaged due to the silicon-based driver substrate 5 being heated during performing the evaporation on the silicon base driver substrate 5, such that the product yield may not be affected.

Specifically, the cathode material may be deposited on the organic light emitting layer 22 and the pixel defining layer 3 and may extend to be deposited on and to be in contact and electrically connected with the metal filled in the plurality of second conductive through holes 132. In this way, one integral cathode electrode 23 for an entire surface is formed, such that homogeneity of the cathode drive signal may be improved, and the voltage drop may be reduced. In some embodiments, the plurality of second conductive through holes 132 may surround the plurality of first conductive through holes 131 to further improve the homogeneity of the cathode drive signal.

In this way, by filling the plurality of second conductive through holes 132 and arranging the cathode electrode 23 after the silicon-based driver substrate 5 being aligned to and bonded with the glass substrate 1, it may be avoided that, during the bonding portions 4 being aligned to and bonded with the bonding electrodes 51, the plurality of connection electrodes 52 may not be aligned to and bonded with the metal filled in the plurality of second conductive through holes 132 at the same time. Therefore, processing difficulty may be reduced, and the product yield may be improved.

Further, after preparing the cathode electrode 23, the method may further include: preparing the encapsulation layer on the side of the cathode electrode away from the glass substrate to encapsulate the plurality of light emitting units.

Specifically, the encapsulation layer 24 may be a laminated structure formed by an organic encapsulation layer and an inorganic encapsulation layer that are laminated, such that effectiveness of encapsulation may be ensured, external water and oxygen may be isolated, invasion of the water and the oxygen, which may lead to failure of the light emitting units 2, may be avoided.

In some embodiments, as shown in FIG. 1b, a size of the silicon-based driver substrate 5 may be made slightly greater than a size of the glass substrate 1. That is, a circumferential edge of the silicon-based driver substrate 5 may protrude out of the glass substrate 1. It is understood that, compared to the method in which the organic light emitting layer 22, the cathode electrode 23, and the encapsulation layer 24 are prepared sequentially on the glass substrate 1 and are subsequently bonded with the silicon-based driver substrate 5, in the present embodiment, the bonding portions 4 on the glass substrate 1 may be bonded with the silicon-based driver substrate 5 firstly, and subsequently, the cathode electrode 23 and the encapsulation layer 24 may be prepared. In this way, the encapsulation layer 24 may extend from the first surface 11 of the glass substrate 1 along the side of the glass substrate 1 to reach the side surface of the protective layer 55 away from the monocrystalline silicon substrate 53, such that the gap between the silicon-based driver substrate 5 and the glass substrate 1 may be sealed, such that the water and the oxygen may be isolated, preventing the water and the oxygen from invading to corrode the bonding portions 4 and the bonding electrodes 51, such that bonding failure may be prevented.

The present disclosure provides the method of manufacturing the display panel. The method includes: providing a glass substrate 1; preparing the plurality of anode electrodes 21 on the first surface 11 of the glass substrate 1; preparing the plurality of bonding portions 4 on the second surface 12 of the glass substrate 1; preparing the pixel defining layer 3 and the organic light-emitting layer 22 sequentially on the side of the plurality of anode electrodes away from the glass substrate 1; providing the silicon-based driver substrate 5, the silicon-based driver substrate 5 including the plurality of bonding electrodes 51; each of the plurality of bonding electrodes 51 having the second snap portion 511; one of the first snap portion 41 and the second snap portion 511 being the recessed structure, and the other being the protruding structure; aligning and bonding the silicon-based driver substrate 5 to the glass substrate 1 arranged with the organic light emitting layer 22, enabling the plurality of bonding electrodes 51 to be one-to-one aligned and bonded to the plurality of bonding portions 4 and enabling the protruding structure to be embedded in the recessed structure. In this way, the light emitting units 2 may be prepared on the glass substrate 5 firstly, and subsequently, the light emitting units 2 may be bonded to the silicon-based driver substrate 5, such that the light emitting units 2 may not be directly prepared on the silicon-based driver substrate 5, and any damage to the pixel driver circuit 54, which may be caused by directly preparing the light emitting units 2 on the silicon-based driver substrate 5, may be avoided, and the product yield may not be affected. Further, by arranging one of the first snap portion 41 and the second snap portion 42 as the recessed structure and arranging the other one of the first snap portion 41 and the second snap portion 42 as the protruding structure, and by embedding the protruding structure in the recessed structure, the bonding contact area between the bonding portion 4 and the bonding electrode 51 may be increased, and the contact resistance is reduced. Therefore, the signal transmission efficiency between the bonding electrodes 51 of the silicon-based driver substrate and the anode electrodes 21 of the light emitting units 2 may be effectively improved. In addition, embedding of the first snap portion 41 and the second snap portion 42 may prevent relative displacement between the glass substrate 1 and the silicon-based driver substrate 5, such that the contact resistance may not be affected. Furthermore, the embedding may improve an extent of bonding between the glass substrate 1 and the silicon-based driver substrate 5, such that the contact resistance may not be affected due to unstable bonding therebetween.

The above is only an implementation of the present disclosure, and is not intended to limit the scope of the present disclosure. Any equivalent structure or equivalent process transformation performed based on the contents of the specification and the accompanying drawings of the present disclosure, applied directly or indirectly in other related technical fields, shall be equivalently included in the scope of the present disclosure.

What is claimed is:

1. A display panel, comprising:
a glass substrate, comprising a first surface and a second surface opposite to the first surface, wherein the glass substrate have a plurality of conductive through holes extending from the first surface to the second surface; the plurality of the conductive through holes comprises a plurality of first conductive through holes;
a plurality of light emitting units, arranged on the first surface of the glass substrate; wherein each of the plurality of light emitting units comprises an anode electrode, an organic light emitting layer and a cathode electrode that are stacked sequentially in a direction extending away from the glass substrate;
a plurality of bonding portions, arranged on the second surface of the glass substrate; wherein each of the plurality of bonding portions is electrically connected to the anode electrode of a respective one of the plurality of light emitting units through a respective one of the plurality of first conductive through holes;
a silicon-based driver substrate, arranged on a side of the second surface of the glass substrate and comprising a plurality of bonding electrodes; wherein the plurality of bonding electrodes is one-to-one aligned to and bonded with the plurality of bonding portions;
wherein, each of the plurality of bonding portions has a first snap portion, and each of the plurality of bonding electrodes has a second snap portion; one of the first snap portion and the second snap portion is a recessed structure, and the other one of the first snap portion and the second snap portion is a protruding structure, the protruding structure is embedded in the recessed structure.

2. The display panel according to claim 1, wherein the protruding structure comprises a plurality of protruding portions that are spaced apart from each other; and the recessed structure comprises a plurality of recesses that are spaced apart from each other; each of the plurality of protruding portions is embedded in a respective one of the plurality of recesses.

3. The display panel according to claim 2, wherein the plurality of protruding portions are in parallel to each other and are spaced apart from each other; and the plurality of recesses are in parallel to each other and are spaced apart from each other.

4. The display panel according to claim 2, wherein a top of at least one of the plurality of protruding portions has a sub-protruding portion; and a bottom of at least one of the plurality of recesses has a sub-recess; the sub-protruding portion is embedded in the sub-recess.

5. The display panel according to claim 2, wherein along a direction perpendicular to the glass substrate, each of a cross section of each of the plurality of protruding portions and a cross section of each of the plurality of recesses is triangular.

6. The display panel according to claim 2, wherein along a direction perpendicular to the glass substrate, each of a cross section of each of the plurality of protruding portions and a cross section of each of the plurality of recesses is trapezoidal.

7. The display panel according to claim 2, wherein each of the plurality of recesses has a recess side wall and a recess bottom wall, an angle between the recess side wall and the recess bottom wall is greater than 90 degrees.

8. The display panel according to claim 7, wherein each of the plurality of protruding portions has a protrusion side wall and a protrusion top wall, an angle between the protrusion side wall and the protrusion top wall is greater than 90 degrees.

9. The display panel according to claim 7, wherein at least one of the plurality of recessed structure has an open-ended structure, and an outer side wall of the at least one recessed structure is recessed towards an interior of the at least one recessed structure.

10. The display panel according to claim 1, wherein the cathode electrode of one of the plurality of light emitting units is extending to be connected to the cathode electrode of another one of the plurality of light emitting units, allowing the plurality of light emitting units to have one common cathode electrode.

11. The display panel according to claim 1, wherein the glass substrate is further arranged with an encapsulation layer; the encapsulation layer covers a side of the cathode electrode away from the anode electrode and extends to reach the silicon-based driver substrate.

12. The display panel according to claim 1, wherein the silicon-based driver substrate further comprises a plurality of connection electrodes, and the plurality of the conductive through holes further comprise a plurality of second conductive through holes; metal is filled in the plurality of second conductive through holes; the cathode electrode is in contact with and is electrically connected to the metal filled in the plurality of second conductive through holes; the metal filled in the plurality of second conductive through holes is in contact with and is electrically connected to the plurality of connection electrodes; the metal filled in each of the plurality of second conductive through holes has the first snap portion, and each of the plurality of connection electrode has the second snap portion.

13. A method of manufacturing a display panel, comprising:
providing a glass substrate, wherein the glass substrate comprises a first surface and a second surface opposite to the first surface; the glass substrate has a plurality of conductive through holes extending from the first surface to the second surface;
preparing a plurality of anode electrodes on the first surface of the glass substrate and preparing a plurality of bonding portions on the second surface of the glass substrate; wherein each of the plurality of bonding portions is electrically connected to a respective one of the plurality of anode electrodes through a respective one of the plurality of conductive through holes; each of the plurality of bonding portions has a first snap portion;
preparing a pixel defining layer and a plurality of organic light emitting layers sequentially on a side of the plurality of the anode electrodes away from the glass substrate;
providing a silicon-based driver substrate; wherein the silicon-based driver substrate comprises a plurality of bonding electrodes, each of the plurality of bonding electrodes has a second snap portion; one of the first snap portion and the second snap portion is a recessed structure, and the other one of the first snap portion and the second snap portion a protruding structure;
aligning and bonding the silicon-based driver substrate with the glass substrate arranged with the plurality of organic light emitting layers, wherein the plurality of bonding electrodes are in one-to-one aligned and bonded with the plurality of bonding portions; and the protruding structure is embedded in the recessed structure.

14. The method according to claim 13, wherein, the plurality of the conductive through holes comprises a plurality of first conductive through holes; and the preparing a plurality of anode electrodes on the first surface of the glass substrate and preparing a plurality of bonding portions on the second surface of the glass substrate, comprises:
arranging a photoresist layer on the second surface of the glass substrate; wherein the photoresist layer covers the plurality of first conductive through holes;
exposing and developing the photoresist layer to form a plurality of receiving grooves on a side of the photoresist layer near the glass substrate, wherein the plurality of receiving grooves are one-to-one correspondingly connected with the plurality of first conductive through holes; a bottom of each of the plurality of receiving grooves has a concave-convex structure for preparing the first snap portion;
filling metal in the plurality of first conductive through holes and the plurality of receiving grooves;
and forming a metal layer on the first surface of the glass substrate;
patterning the metal layer to form the plurality of anode electrodes;
removing the photoresist layer, the metal inside the plurality of receiving grooves forming the plurality of bonding portions.

15. The method according to claim 14, wherein the plurality of conductive through holes further comprise a plurality of second conductive through holes; the silicon-based driver substrate further comprises a plurality of connection electrodes; the plurality of connection electrodes are disposed in one-to-one alignment with the plurality of second conductive through holes; and the aligning and bonding the silicon-based driver substrate with the glass substrate arranged with the plurality of organic light emitting layers, comprises:
filling metal in the plurality of second conductive through holes, wherein the metal filled in the plurality of second conductive through holes is in contact with and electrically connected to the plurality of connection electrodes; and
preparing the cathode electrode on a side of the plurality of organic light emitting layers away from the glass substrate, wherein the cathode electrode is in contact with and electrically connected to the metal filled in the plurality of second conductive through holes.

16. The method according to claim 13, wherein laser etching is performed on the glass substrate to form the plurality of conductive through holes, each of the plurality of conductive through holes has a diameter in a range of 50 μm to 100 μm.

17. The method according to claim 14, wherein the plurality of conductive through holes comprise a plurality of first conductive through holes and a plurality of second conductive through holes; the photoresist layer fully fills the plurality of first conductive through holes and the plurality of second conductive through holes; a portion of the photoresist layer filling the plurality of first conductive through holes is removed; and another portion of the photoresist layer filling the plurality of second conductive through holes is retained.

18. The method according to claim 13, wherein the pixel defining layer covers edges of the plurality of anode electrodes and exposes a partial surface of each of the plurality of anode electrodes.

19. The method according to claim 13, wherein the protruding structure comprises a plurality of protruding portions that are spaced apart from each other; and the recessed structure comprises a plurality of recesses that are spaced apart from each other; each of the plurality of protruding portions is embedded in a respective one of the plurality of recesses.

20. The method according to claim 19, wherein the plurality of protruding portions are in parallel to each other and are spaced apart from each other, and the plurality of recesses are in parallel to each other and are spaced apart from each other.
